(19) United States
(12) Patent Application Publication
(10) Pub. No.: US 2025/0106983 A1
(43) Pub. Date: Mar. 27, 2025

(54) STIFFENER ARCHITECTURES FOR GLASS EDGE PROTECTION

(71) Applicant: Intel Corporation, Santa Clara, CA (US)

(72) Inventors: Bohan SHAN, Chandler, AZ (US); Kyle ARRINGTON, Gilbert, AZ (US); Dingying David XU, Chandler, AZ (US); Ziyin LIN, Chandler, AZ (US); Timothy GOSSELIN, Phoenix, AZ (US); Elah BOZORG-GRAYELI, Tempe, AZ (US); Aravindha ANTONISWAMY, Chandler, AZ (US); Wei LI, Chandler, AZ (US); Haobo CHEN, Chandler, AZ (US); Yiqun BAI, Chandler, AZ (US); Jose WAIMIN, Gilbert, AZ (US); Ryan CARRAZZONE, Chandler, AZ (US); Hongxia FENG, Chandler, AZ (US); Srinivas Venkata Ramanuja PIETAMBARAM, Chandler, AZ (US); Gang DUAN, Chandler, AZ (US); Bin MU, Tempe, AZ (US); Mohit GUPTA, Chandler, AZ (US); Jeremy D. ECTON, Gilbert, AZ (US); Brandon C. MARIN, Gilbert, AZ (US); Xiaoying GUO, Chandler, AZ (US); Ashay DANI, Chandler, AZ (US)

(21) Appl. No.: 18/373,457

(22) Filed: Sep. 27, 2023

(51) Int. Cl. H05K 1/02; H05K 1/03

(52) U.S. Cl. CPC H05K 1/0271; H05K 1/0306; H05K 2201/2009

(57) ABSTRACT

Embodiments disclosed herein include glass core package substrates with a stiffener. In an embodiment, an apparatus comprises a substrate with a first layer with a first width, where the first layer is a glass layer, a second layer under the first layer, where the second layer has a second width that is smaller than the first width, and a third layer over the first layer, where the third layer has a third width that is smaller than the first width. In an embodiment, the apparatus further comprises a metallic structure with a first portion and a second portion, where the first portion is over a top surface of the substrate and the second portion extends away from the first portion and covers at least a sidewall of the first layer.

### BACKGROUND

As semiconductor packaging architectures continue towards more complex and more compact systems, new material solutions may be used to enable such architectures. One promising candidate for use in packaging substrates is a glass core layer. In such substrates, a glass core is sandwiched between overlying and underlying buildup layers. Electrically conductive vias are provided through the glass core in order to provide electrical coupling between the overlying and underlying buildup layers. Glass cores are beneficial because they can provide high density vias. Glass is also a high modulus material, which provides desirable stiffness to the overall package substrate.

However, singulation of glass core substrates through conventional processes and subsequent substrate handling can generate micro-cracks and other defects around the edges of the glass core. The application of stress from the overlying and underlying buildup layers can cause the micro-cracks to further propagate into the glass core. Ultimately, this can lead to serious damage to the package substrate. For example, damage can effect electrical performance of vias through the glass core, and damage can even result in complete device failure. Accordingly, yields for existing glass core manufacturing flows are low.

### BRIEF DESCRIPTION OF THE DRAWINGS

FIG. 1A is a cross-sectional illustration of a glass core package substrate with stress applied to the ends of the glass core by the overlying and underlying buildup layers, in accordance with an embodiment.

FIG. 1B is a cross-sectional illustration of a glass core package with portions of the buildup layers over the ends of the glass core removed in order to reduce stress on the glass core, in accordance with an embodiment.

FIG. 1C is a cross-sectional illustration of a glass core package with the buildup layer ends having tapered profiles, in accordance with an embodiment.

FIG. 1D is a cross-sectional illustration of a glass core package with buildup layers and a solder resist layer, in accordance with an embodiment.

FIG. 2 is a perspective view illustration of a package substrate with a stiffener that includes vertical portions for protecting exposed edges of a glass core, in accordance with an embodiment.

FIG. 3A is a cross-sectional illustration of a package substrate with a glass core, in accordance with an embodiment.

FIG. 3B is a cross-sectional illustration of the package substrate as a stiffener is brought towards the package substrate, in accordance with an embodiment.

FIG. 3C is a cross-sectional illustration of the package substrate after the stiffener is coupled to the package substrate by an adhesive, in accordance with an embodiment.

FIG. 4 is a plan view illustration of a stiffener that indicates the fold lines in order to provide vertical portions to protect exposed glass cores, in accordance with an embodiment.

FIG. 5 is a cross-sectional illustration of a package substrate with a glass core that includes a dual sided stiffener that is coupled to the package substrate by an adhesive that surrounds an exposed end of the glass core, in accordance with an embodiment.

FIG. 6A is a plan view illustration of a panel level sheet that includes a plurality of units after the buildup layer is removed from the saw streets, in accordance with an embodiment.

FIG. 6B is a cross-sectional illustration of a pair of package substrate units that are separated by a saw street, in accordance with an embodiment.

FIG. 6C is a plan view illustration of the panel level sheet after adhesive is applied in the saw streets, in accordance with an embodiment.

FIG. 6D is a cross-sectional illustration of the package substrates after an adhesive is applied in the saw streets, in accordance with an embodiment.

FIG. 6E is a plan view illustration of the panel level sheet after a stiffener is applied over the saw streets, in accordance with an embodiment.

FIG. 6F is a cross-sectional illustration of the package substrates after stiffeners are attached above and below the saw streets, in accordance with an embodiment.

FIG. 6G is a cross-sectional illustration of the package substrates after a singulation process is used to separate the individual package substrates, in accordance with an embodiment.

FIG. 7 is a perspective view illustration of a package substrate that is inserted into a stiffener that wraps around edges of the package substrate, in accordance with an embodiment.

FIG. 8A is a cross-sectional illustration of the package substrate in FIG. 7 along line A-A′, in accordance with an embodiment.

FIG. 8B is a cross-sectional illustration of the package substrate in FIG. 7 along line B-B′, in accordance with an embodiment.

FIG. 9 is a cross-sectional illustration of an electronic system that includes a package substrate with a stiffener that protects protruding portions of a glass core, in accordance with an embodiment.

FIG. 10 is a schematic of a computing device built in accordance with an embodiment.

### EMBODIMENTS OF THE PRESENT DISCLOSURE

Described herein are electronic systems, and more particularly, stiffener architectures to protect a protruding glass core in a package substrate, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

As noted above, enabling glass core based package substrates has substantial benefits for the electronics packaging industry. However, certain hurdles still need to be overcome in order to enable high yielding, robust, and relatively low cost solutions. One particular issue is the tendency for the glass cores to develop defects that can lead to fracture, delamination, excessive warpage, and the like.

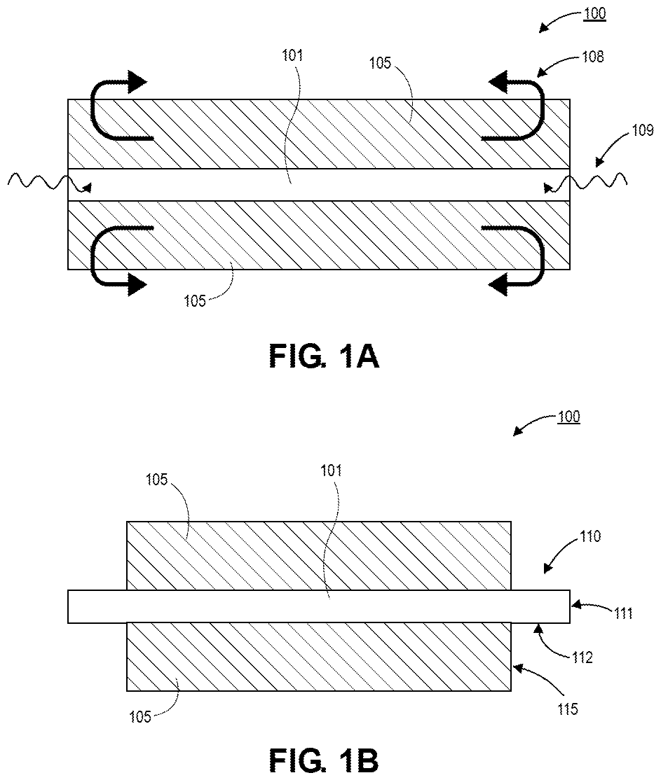

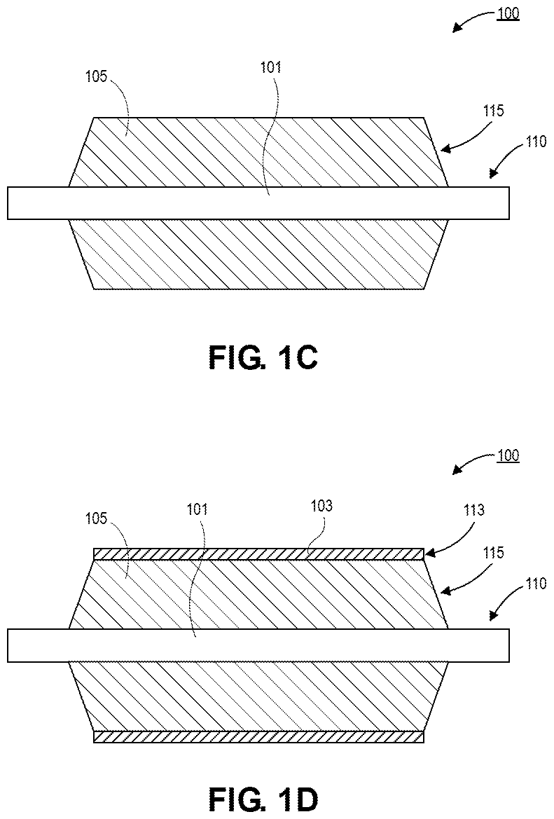

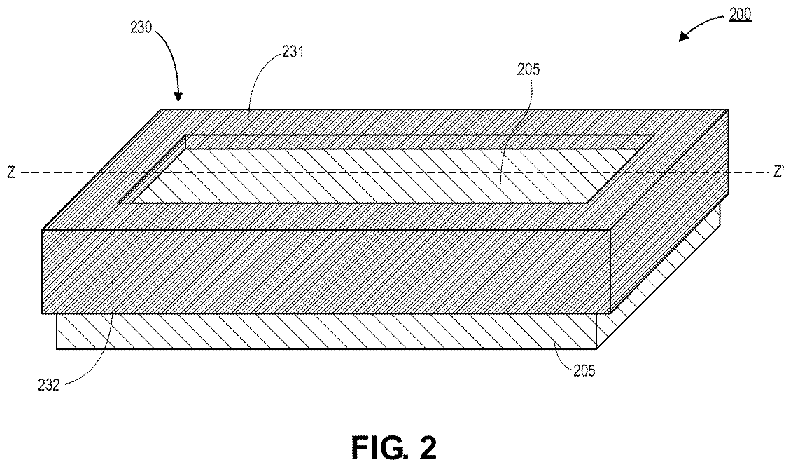

Referring now to FIG. 1A, a cross-sectional illustration of a typical package substrate 100 with a glass core 101 is shown. The package substrate 100 includes the glass core 101 with buildup layers 105 above and below the glass core 101. The buildup layers 105 may comprise traditional organic buildup film and the like. In existing solutions, the singulation of the package substrate 100 is done with standard sawing processes that pass through both the buildup layers 105 and the glass core 101. That is, the edges of the buildup layers 105 will generally be substantially coplanar with the edges of the glass core 101.

However, as indicated by the looping arrows 108, the singulation process leads to stress within the buildup layers 105—especially at the edges of the buildup layers 105. This stress can then be transferred into the glass core 101, as indicated by the arrows 109. The stress concentration at the edge of the glass core 101 may lead to the generation of defects, such as micro-cracks. Additionally, existing defects may be propagated further towards the middle of the glass core 101. This can lead to catastrophic damage to the glass core 101 and completely ruin the package substrate 100.

Accordingly, solutions for reducing the stress around the edges of the glass core 101 have been proposed. One such solution is shown in FIG. 1B. In FIG. 1B, the buildup layers 105 are removed from over the edges of the glass core 101. For example, protrusions 110 may be provided along each edge of the package substrate 100. The protruding regions 110 may be defined by horizontal surfaces 112 and a sidewall surface 111. That is, the sidewall 111 of the glass core 101 may be offset from the sidewalls 115 of the buildup layers 105. The protrusion may have a length of 1 μm or more, 5 μm or more, 10 μm or more, or 25 μm or more.

In FIG. 1B, the sidewalls 115 of the buildup layers 105 are substantially vertical. In other embodiments, as shown in FIG. 1C, the sidewalls 115 may have a tapered profile. The tapered profile of the sidewalls 115 may be the result of the processing used to remove the edges of the buildup layers 105. For example, when a laser drilling or ablation process is used to remove portions of the buildup layers 105, the sidewalls 115 may have the tapered profile. The degree of taper (or slope) of the sidewalls 115 may be dependent on processing variables used in the removal of the buildup layers 105.

Additionally, as shown in FIG. 1D, the package substrate 100 may also include a solder resist layer 103 over the top and/or bottom of the buildup layers 105. The solder resist layer 103 may be considered part of the buildup layer in the following descriptions detailed below. That is, while the Figures may not show a distinct solder resist layer 103 in all instances, the presence of a buildup layer 105 may be used to imply that a solder resist layer is present. In the illustration shown in FIG. 1D, the solder resist 103 has a substantially vertical sidewall 113. Though, the sidewall 113 may also be sloped or tapered, similar to the sidewall 115 of the buildup layers 105.

Removing the buildup layers 105 from over the protrusions 110 lessens the stress that is induced into the glass core 101. However, the glass core 101 is still a brittle and otherwise fragile layer. As such, care is needed in order to avoid contact with the protrusions throughout the rest of the assembly process. With existing process flows, this extra protection may not be available. Therefore, the risk of damage and the probability of low yields is still unacceptably high.

Accordingly, embodiments disclosed herein include protective features that are integrated with the package substrate. In one embodiment, the protective feature is part of a stiffener. The stiffener is an existing component to many package substrates. Generally, the stiffener is a ring of stiff or rigid material that is provided around the edges of the package substrate. The rigidity of the stiffener helps to reduce the amount of warpage seen in the package substrate. Embodiments disclosed herein leverage the stiffener to provide additional functionality. Namely, the stiffener provides the typical warpage reduction function and provides protection to the protruding portions of the glass core. In an embodiment the stiffener may be a metallic structure. In some instances, a stiffener and a metallic structure may refer to the same type of structure or structures. Though, a stiffener may also include non-metallic structures in some embodiments.

In one embodiment, the stiffener includes a first portion on the top of the package substrate. The first portion is a ring proximate to the edges of the package substrate. A second portion of the stiffener is an extension (e.g., vertical, angled, curved, etc.). The extension of the second portion extends down along the sidewall of the package substrate. The second portion extends down at least far enough in order to cover the exposed sidewall of the glass core.

In another embodiment, the stiffener includes a top stiffener and a bottom stiffener. The top stiffener and the bottom stiffener are on the top and bottom surfaces of the package substrate, respectively. Both the top stiffener and the bottom stiffener extend out past an edge of the buildup layers. In some instances edges of the top stiffener and the bottom stiffener are substantially coplanar with the edge of the glass core. An adhesive may be provided between the top stiffener and the bottom stiffener so that the adhesive surrounds the protruding portion of the glass core.

In yet another embodiment, the stiffener envelops the package substrate. For example, the stiffener includes edges that wrap down and around the bottom of the package substrate. In such instances, the package substrate is slotted into the stiffener. The stiffener has a pair of open ends and a pair of closed ends. The package substrate is inserted into the stiffener through the open ends. Such an embodiment provides complete protection of the glass core protrusions on the closed ends, and the open ends can provide some degree of protection by extending out further than the glass core protrusions.

Referring now to FIG. 2, a perspective view illustration of a package substrate 200 is shown, in accordance with an embodiment. In an embodiment, the package substrate 200 may include a multi-layer substrate. For example, buildup layers 205 may be provided above and below a core (not visible in FIG. 2). The buildup layers 205 may be organic buildup material, such as organic buildup film layers. Electrically conductive features, such as traces, vias, pads, etc., may be provided in and/or on the buildup layers 205. The core may provide vias in order to pass signals and/or power between the top buildup layer 205 and the bottom buildup layer 205.

In an embodiment, the core may be a glass core. As described above, the use of a glass core can provide certain benefits. In order to reduce the generation and/or propagation of defects in the glass core, the edge portions of the buildup layers 205 may be recessed to provide exposed regions of the glass core, which may sometimes be referred to as glass core protrusions or, simply, protrusions.

In FIG. 2, the protrusions are covered by portions of the stiffener 230. The stiffener 230 may be a material that has a high modulus. For example, the stiffener 230 may include materials comprising stainless steel, copper, aluminum, or the like. Different alloys, different layer combinations, and the like may also be used to form the stiffener 230. For example, a coating may be provided over the stiffener 230 in some instances.

In the embodiment shown in FIG. 2, the stiffener 230 includes a first portion 231 and a second portion 232. The first portion 231 is positioned over the top surface of the package substrate 200. The first portion 231 may be a ring, such as a rectangular ring, that is provided along the outer edge of the top buildup layer 205. The second portions 232 may be vertical portions that extend down along sidewalls of the package substrate 200. The second portions 232 may be a monolithic part of the stiffener with the first portion 231. For example, the second portions 232 may be folded down from the first portion 231. As such, the second portions 232 and the first portion 231 may have substantially the same thickness since they may be sourced from a single sheet of material.

In the illustrated embodiment, the first portion 231 may have four outer edges, and second portions 232 may extend down from each of the four outer edges. The second portions 232 may extend down at least partially along the height of the package substrate 200. More particularly, the second portions 232 may extend down so that they cover at least the glass core. Covering the glass core protects the glass core from accidental contact during subsequent handling and/or assembly processes.

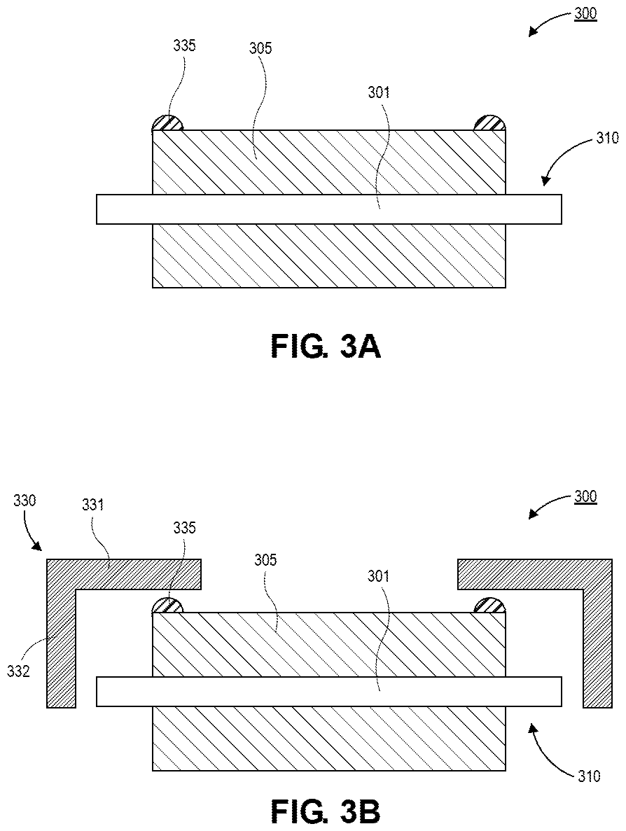

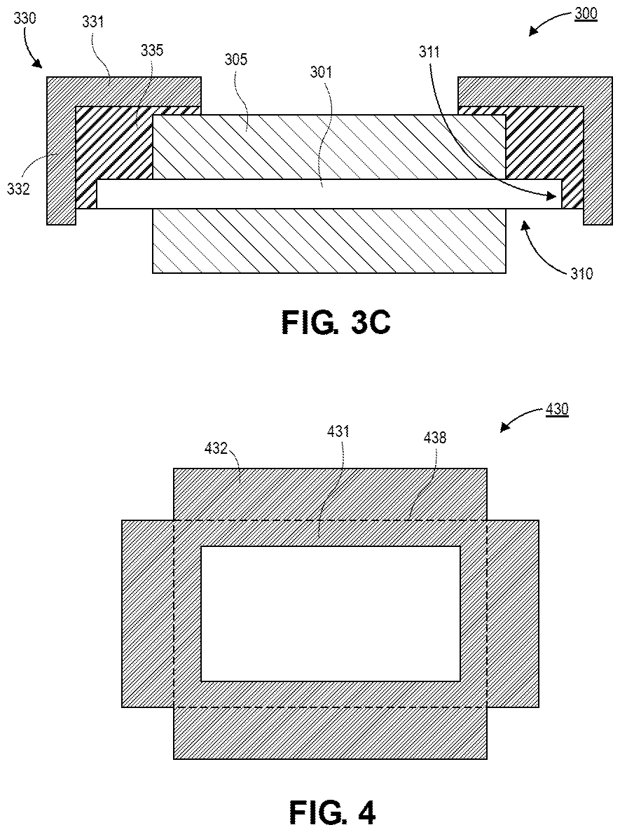

Referring now to FIGS. 3A-3C, a series of cross-sectional illustrations depicting a process for forming a package substrate 300 with a protective stiffener similar to the one shown in FIG. 2 is shown, in accordance with an embodiment. The cross-section shown in FIGS. 3A-3C may be similar to the cross-section indicated as Z-Z′ in FIG. 2.

Referring now to FIG. 3A, a cross-sectional illustration of a package substrate 300 is shown, in accordance with an embodiment. The package substrate 300 may include a glass core 301. As used in embodiments disclosed herein, glass cores 301 may be substantially all glass. The glass core 301 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass core 301 may be distinguished from, for example, the “prepreg” or “RF4” core of a Printed Circuit Board (PCB) substrate which typically comprises glass fibers embedded in a resinous organic material such as an epoxy. More particularly, the glass core 301 may be any suitable glass formulation that has the necessary mechanical robustness and compatibility with semiconductor packaging manufacturing and assembly processes. For example, the glass core 301 may comprise aluminosilicate glass, borosilicate glass, alumino-borosilicate glass, silica, fused silica, or the like. In some embodiments, the glass core 301 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, and Zn. More generally, the glass core 301 may comprise silicon and oxygen, as well as any one or more of aluminum, boron, magnesium, calcium, barium, tin, sodium, potassium, strontium, phosphorus, zirconium, lithium, titanium, and zinc. In an embodiment, the glass core 301 may comprise at least 23 percent silicon (by weight) and at least 26 percent oxygen (by weight). In some embodiments, the glass core 301 may further comprise at least 5 percent aluminum (by weight). In an embodiment, the glass core 301 has a thickness that is between approximately 100 μm and approximately 1,000 μm. Though, embodiments may include thinner or thicker glass cores 301. As used herein, “approximately” may refer to a range of values within ten percent of the stated value. For example, approximately 100 μm may refer to a range from 90 μm to 110 μm. In an embodiment, the glass core 301 may be a rectangular prism. That is, a plan view of the glass core 301 will be illustrated as a rectangle in some embodiments.

The glass core 301 may be sandwiched between overlying and underlying buildup layers 305. The buildup layers 305 may be organic buildup materials, such as layers of buildup film and the like. The buildup layers 305 may also include solder resist layers (not shown) at the topmost and/or bottommost surfaces.

In an embodiment, a width of the glass core 301 may be greater than widths of the buildup layers 305. In some instances the buildup layers 305 have widths equal to each other, and in other embodiments, the buildup layers 305 have different widths. However, the reduced widths of the buildup layers 305 result in the formation of portions of the glass core 301 that are exposed. These protrusions 310 are the features that are to be physically protected by the stiffener.

In an embodiment, adhesive 335 may be applied to the top surface of the package substrate 300. The adhesive 335 may be applied along the outer edges of the package substrate 300 in anticipation of the attachment of the stiffener. The adhesive 335 may be any suitable adhesive material that is at least partially flowable. The adhesive 335 may comprise an epoxy material, a silicone material, or the like. In some instances, the adhesive 335 is electrically conductive. For example, electrically conductive filler particles (e.g., silver, copper, carbon nanotubes, etc.) may be distributed within the adhesive matrix. A conductive adhesive 335 may be beneficial for improving the grounding of the stiffener in some embodiments. In other embodiments, the adhesive 335 may be an insulating material.

Referring now to FIG. 3B, a cross-sectional illustration of the package substrate 300 after a stiffener 330 is brought towards the package substrate 300 is shown, in accordance with an embodiment. The stiffener 330 may include a first portion 331 and second portions 332. The first portion 331 may be a ring that is positioned over a top surface of the package substrate 300. The first portion 331 may be substantially parallel to the top surface of the upper buildup layer 305. An inner surface of the first portion 331 may be provided over a surface of the buildup layer 305, and an outer surface of the first portion 331 may be outside of the footprint of the buildup layer 305. Additionally, the outer surface of the first portion 331 may be outside the footprint of the glass core 301.

In an embodiment, the second portions 332 extend down along the sidewall of the package substrate 300. Since the second portions 332 are attached to the outer edges of the first portion 331, the second portions 332 may also be outside of the footprint of the buildup layers 305 and the glass core 301. This allows for the second portions 332 to cover the sidewall surfaces of the glass core 301. As used herein, the phrases “cover”, “covering”, or “covered” may refer to a configuration where a structure blocks the view of an adjacent component. For example, if a straight line extending out from a sidewall of the glass core 301 (e.g., a line parallel to the top surface of the glass core 301 that starts at the sidewall of the protrusion 310) were to intersect the second portions 332 of the stiffener 330, then the stiffener 330 would be considered as covering the sidewall of the glass core 301. That is, when a first component “covers” a second component, there does not need to be direct physical contact between the first component and the second component.

Referring now to FIG. 3C, a cross-sectional illustration of the substrate 300 after the stiffener 330 is compressed against the adhesive 335 and physically coupled to the buildup layer 305 is shown, in accordance with an embodiment. In an embodiment, the stiffener 330 compresses the adhesive 335 and causes the adhesive 335 to spread. The adhesive 335 may spread so that is at least partially fills the gap between the second portions 332 of the stiffener 330 and the sidewall of the buildup layer 305. Additionally, the adhesive 335 may at least partially fill a gap between the sidewall 311 of the glass core 301 and the second portions 332 of the stiffener 330. Accordingly, the protrusion 310 is shielded (or covered) by the stiffener 330 and provided mechanical support (e.g., through direct physical contact) by the adhesive 335.

In an embodiment, the bottom of the second portions 332 of the stiffener 330 may be at least even with a bottom of the glass core 301. In other embodiments, the bottom of the second portions 332 may extend past the bottom of the glass core 301 so that it at least partially covers a portion of the bottom buildup layer 305. In some instances, the bottom of the second portions 332 may be substantially coplanar with a bottom of the buildup layer 305 underlying the glass core 301.

Referring now to FIG. 4, a plan view illustration of a stiffener 430 at a stage of manufacture is shown, in accordance with an embodiment. The stiffener 430 in FIG. 4 represents the state of the stiffener 430 after it has been fabricated from a sheet of metal or the like. For example, the stiffener 430 may be stamped from a larger sheet. At this point of the manufacture, the stiffener 430 is entirely planar. That is, the first portion 431 and the second portions 432 are in the same plane as each other.

The first portion 431 may be a ring. For example, the first portion 431 may be rectangular. An inner surface of the first portion 431 may define a rectangular opening, and an outer surface of the first portion 431 may be coincident with fold lines 438. The fold lines 438 are indicated in FIG. 4 with dashed lines for convenience. Though, in actuality, there may be no discernable mark along the location of the fold lines 438 before the folds are actually made. The second portions 432 may be rectangular regions that are adjacent to one or more of the outer surfaces of the first portion 431. In the illustrated embodiment, all four outer surfaces of the first portion 431 have an associated second portions 432. Though in some embodiments, one or more of the outer surfaces of the first portion 431 may not include an adjacent second portions 432.

After the stamping process used to form the cutout of the stiffener 430, a folding process may be used to form a stiffener similar to embodiments described in greater detail above. The folding process may be done through automated processes, or the folding may be done manually. The folding process may result in a stiffener 430 that has a first portion 431 that is monolithically connected to a second portions 432 with a fold or seam between them.

While embodiments disclosed herein describe a monolithic stiffener, it is to be appreciated that embodiments are not limited to such configurations. For example, any attachment structure may be used in order to couple a first portion 431 to a second portions 432. For example, welding, gluing, or other adhesives may be used to couple the first portion 431 to the second portions 432 in some embodiments. Other fastening mechanisms, such as screws, bolts, clamps, interlocking folds, or the like may also be used to couple the first portion 431 to the second portions 432.

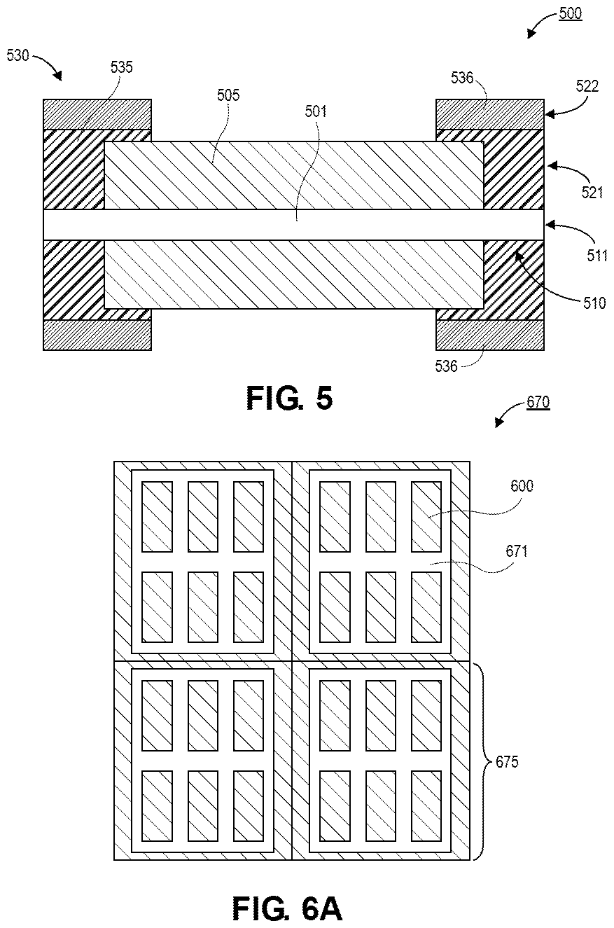

Referring now to FIG. 5, a cross-sectional illustration of a substrate 500 is shown, in accordance with an additional embodiment. In an embodiment, the substrate 500 may comprise a glass core 501. The glass core 501 may be similar in composition and structure to any of the glass cores described in greater detail herein. In an embodiment, buildup layers 505 may be provided above and/or below the glass core 501. Glass core protrusions 510 may extend out past sidewall edges of the buildup layers 505.

In an embodiment, a stiffener 530 may be provided over and/or under the package substrate 500. The material for the stiffener 530 may be similar to the stiffener materials described in greater detail above. In an embodiment, the stiffener 530 may include a top stiffener 536 and a bottom stiffener 536. While both a top stiffener 536 and a bottom stiffener 536 are shown in FIG. 5, it is to be appreciated that in some embodiments, a stiffener 530 may include only a top stiffener 536 or a bottom stiffener 536. In some embodiments, the top stiffener 536 and the bottom stiffener 536 may be the same material. Though, the top stiffener 536 and the bottom stiffener 536 may be different materials as well.

The top and bottom stiffeners 536 may have an inner surface that is provided within a footprint of the buildup layers 505, and an outer surface 522 that is substantially coplanar with a sidewall surface 511 of the glass core 501. As used herein, “substantially coplanar” may refer to two surfaces that are with 2 μm of being coplanar with each other. Generally “substantially coplanar” surfaces have the same slope and orientation, but small variations (e.g., within 5 percent) of each other may still satisfy the necessary condition. That is, manufacturing tolerances will typically prevent two different surfaces from being absolutely coplanar with each other. However, in the case of the surfaces 522 and 511 in FIG. 5, the two surfaces are generated using a single singulation process (e.g., mechanical sawing, as will be described in greater detail below) and will typically be as coplanar as possible given the manufacturing tolerances of the singulation process.

Additionally, an adhesive 535 may be provided between the top stiffener 536 and the bottom stiffener 536. The adhesive 535 may be similar to any of the adhesives described in greater detail herein. The adhesive 535 may also surround the top and bottom surfaces of the protrusion 510 to provide mechanical support to the glass core 501. The outer sidewall 521 of the adhesive 535 may also be substantially coplanar with the sidewall 511 of the glass core 501 in some embodiments.

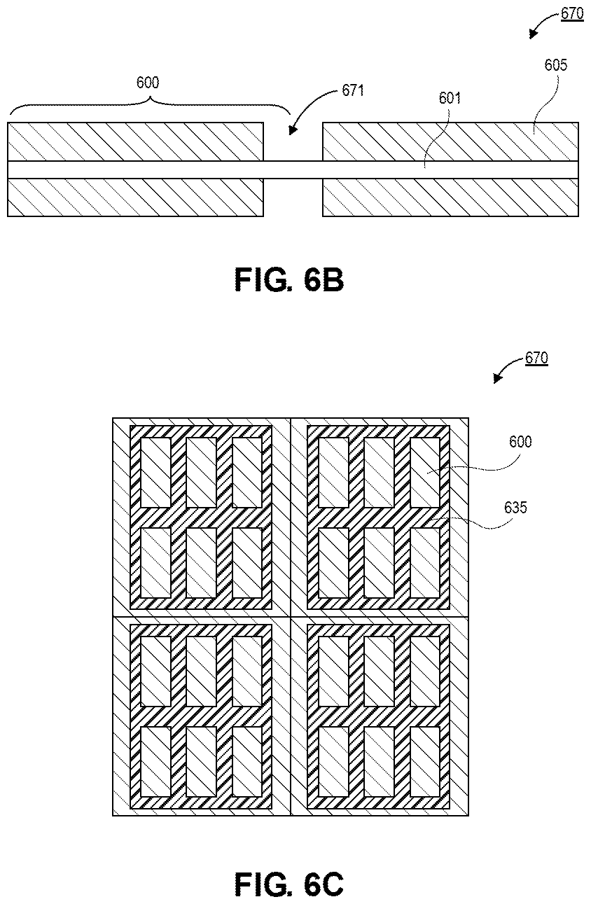

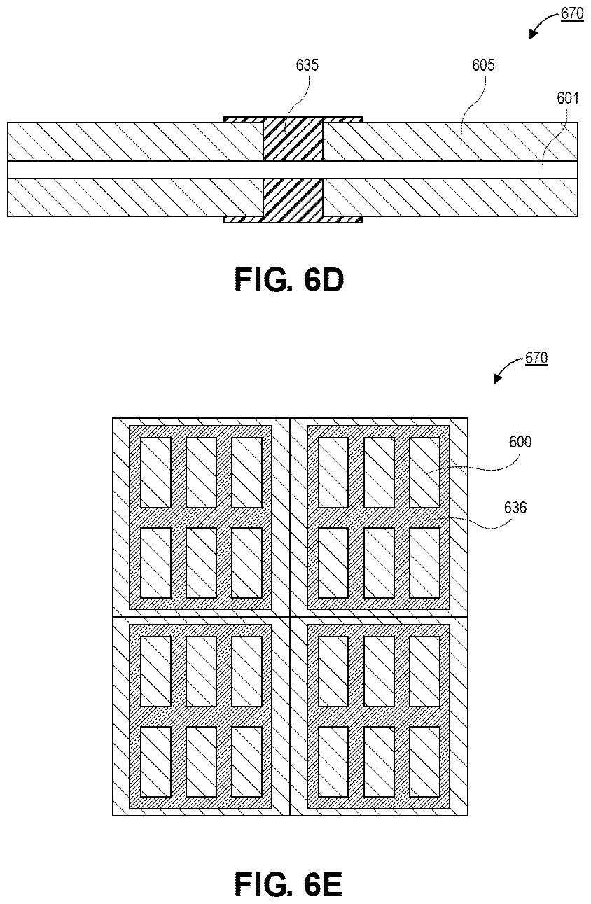

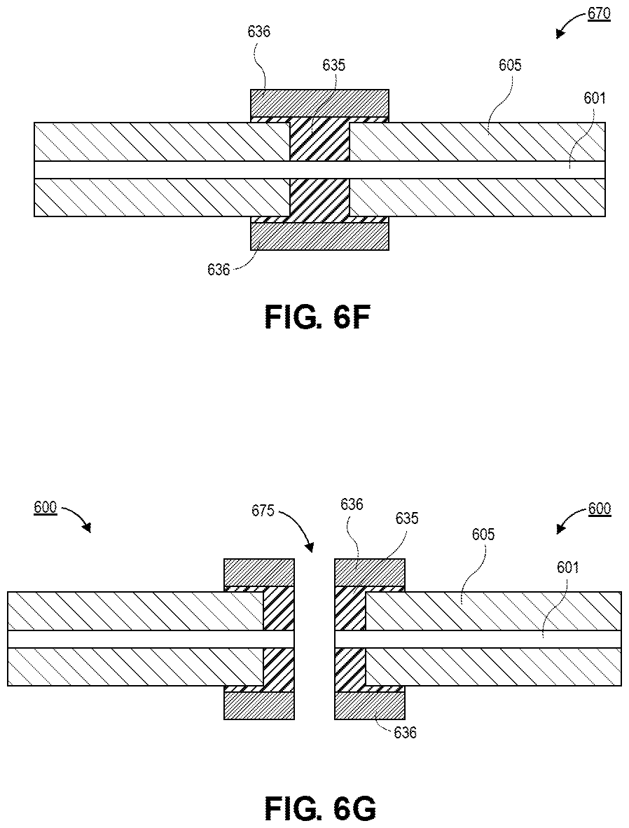

Referring now to FIGS. 6A-6G a series of illustrations depicting a process for forming a package substrate 600 similar to the one shown in FIG. 5 is shown, in accordance with an embodiment. In the illustrated embodiments a mix of panel level plan views and cross-sectional illustrations of a pair of units within the panel are shown for illustrative purposes.

Referring now to FIG. 6A, a plan view illustration of a panel 670 is shown, in accordance with an embodiment. In an embodiment, the panel 670 may include four quarter panels 675 (with each quarter panel separated by a solid line). An array of individual units or package substrates 600 may be provided within each quarter panel 675. While six package substrates 600 are shown in each quarter panel 675 in FIG. 6A, it is to be appreciated that any number of package substrates 600 may be present in the array, depending on the size of the package substrates 600 and the size of the panel 670.

In an embodiment, the package substrates 600 may be separated from each other by saw streets 671. FIG. 6A illustrates the panel 670 after the buildup layer along the saw streets 671 is removed to expose the underlying glass core. The buildup layer may be removed with any suitable process. For example, etching, laser ablation, or the like may be used to remove portions of the buildup layer.

Referring now to FIG. 6B, a cross-sectional illustration of a pair of package substrates 600 within a panel 670 is shown, in accordance with an embodiment. As illustrated, both package substrates 600 are mechanically coupled together by a single continuous glass core 601. The glass core 601 extends through the saw street 671 between the portions of the buildup layer 605. The illustration in FIG. 6B is zoomed in on a single saw street 671. In reality, there may be saw streets around all edges of the package substrate 600.

Referring now to FIG. 6C, a plan view illustration of the panel 670 after an adhesive 635 is applied is shown, in accordance with an embodiment. In an embodiment, the adhesive 635 may be similar to any of the adhesives described in greater detail herein. The adhesive 635 may be applied along the saw streets 671 between the individual package substrate 600 units.

Referring now to FIG. 6D, a cross-sectional illustration of the panel 670 showing the adhesive 635 between a pair of package substrates 600 is shown, in accordance with an embodiment. The volume of the adhesive dispensed may be sufficient to completely fill the saw streets 671. That is, the thickness of the adhesive 635 may be at least equal to that of the buildup layers 605. As shown in FIG. 6D, the adhesive 635 may also overfill the saw streets 671 in some embodiments.

Referring now to FIG. 6E, a plan view illustration of the panel 670 after a stiffener is applied is shown, in accordance with an embodiment. The stiffener may include a top portion 636 and a bottom portion (on the opposite side of the panel 670).

The top portion 636 of the stiffener may be a sheet with cutouts around each of the individual package substrates 600. The top portion of the stiffener 636 may be a material similar to any of the stiffener compositions described in greater detail herein.

Referring now to FIG. 6F, a cross-sectional illustration of the panel 670 after the top and bottom portions 636 of the stiffener are applied is shown, in accordance with an embodiment. The top and bottom portions 636 may span the entire width of the saw streets 671. The edges of the top and bottom portions 636 may be within the footprints of the buildup layers 605. In an embodiment, the adhesive 635 couples the top and bottom portions 636 to the buildup layers 605.

In an embodiment, the top portion 636 and the bottom portion 636 of the stiffener are substantially similar to each other. In other embodiments, a width of the top portion 636 may be different than a width of the bottom portion 636. In other embodiments, a thickness of the top portion 636 may be different than a thickness of the bottom portion 636.

Referring now to FIG. 6G, a cross-sectional illustration of the package substrates 600 after singulation is shown, in accordance with an embodiment. The singulation may be implemented along the saw street 671 with any singulation mechanism. In some instances, a saw is used to form gap 675 between the package substrates 600. Since a single cut is used, the sidewalls of the stiffeners, the adhesive 635, and the glass core 601 will be substantially coplanar, as described in greater detail above.

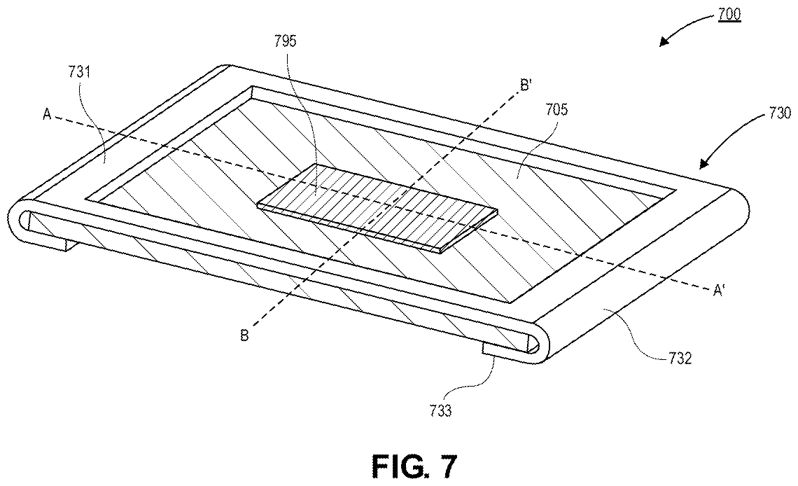

Referring now to FIG. 7, a perspective view illustration of a package substrate 700 is shown, in accordance with another embodiment. In an embodiment, the package substrate 700 may include buildup layers 705 that are provided on opposite sides of a glass core (not visible in FIG. 7). The glass core may include protrusions that need physical protection from a stiffener 730.

The stiffener 730 may include a first portion 731 that is a ring around an outer edge of the package substrate 700. The first portion 731 includes a cutout to accommodate one or more dies 795 that are over the buildup layer 705. The stiffener 730 may also include a second portion 732. The second portion 732 wraps around a sidewall of the package substrate 700 in order to protect or cover the protrusion of the glass core. In the illustrated embodiment, the second portion 732 is curved. Though, the second portion 732 may also be straight (e.g., substantially vertical) in other embodiments. The stiffener 730 may also comprise a third portion 733 that is coupled to the bottom of the second portion 732. The third portion 733 may be substantially parallel to the first portion 731, and the third portion 733 may cover at least a portion of the bottom surface of the package substrate 700.

Such a stiffener 730 architecture may use different assembly processes than those described above. Instead of pressing the stiffener 730 down around the package substrate 700, the package substrate 700 may be slid into the stiffener laterally. Such a configuration may be referred to as being a slotted configuration. In order to allow for such an assembly process, the second portion 732 and the third portion 733 may be present on two opposing outer edges of the first portion 731. The open outer edges may provide protection to any glass core protrusions with alternative approaches, as will be described in greater detail below.

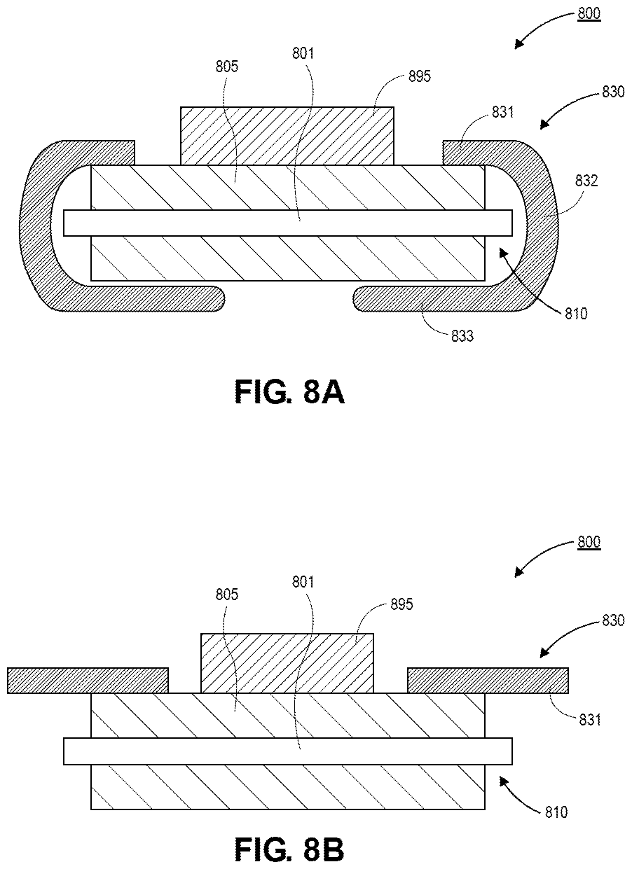

Referring now to FIG. 8A, a cross-sectional illustration of a package substrate 800 is shown, in accordance with an embodiment. In an embodiment, the package substrate 800 may be similar to the package substrate 700 in FIG. 7 along line A-A′. As shown, the package substrate 800 includes a glass core 801 that is sandwiched between a pair of buildup layers 805. The glass core 801 may include protrusions 810 that extend past an edge of the buildup layers 805. In an embodiment, a stiffener 830 wraps around edges of the package substrate 830 in order to cover the protrusions 810. One or more dies 895 may be provided on the top surface of the package substrate 800 within a cutout in the stiffener 830.

As shown, the stiffener 830 is a monolithic structure that comprises a first portion 831, a second portion 832, and a third portion 833. The first portion 831 is over a top surface of the package substrate 800, the second portion 832 covers a sidewall of the package substrate 800 (including the protrusions 810), and the third portion 833 is under the bottom surface of the package substrate 800. While a monolithic stiffener 830 is illustrated, embodiments may also include discrete components that are mechanically coupled together, similar to mechanical coupling solutions described in greater detail above.

In the illustrated embodiment, the stiffener 830 is in direct contact with the package substrate 800. However, an adhesive or other interface material may be provided between the stiffener 830 and the package substrate 800. For example, a fill material or adhesive may be provide around the protrusion 810 between the second portion 832 of the stiffener 830 and the package substrate 800.

Referring now to FIG. 8B, a cross-sectional illustration of the package substrate 800 in a view orthogonal to the one in FIG. 8A is shown in accordance with an embodiment. The view in FIG. 8B is similar to the view along line B-B′ in FIG. 7. Particularly, the view in FIG. 8B illustrates the open ends of the stiffener 830. That is, there is no portion of the stiffener 830 that wraps down along the side of the package substrate 800 in order to cover the protrusion 810 of the glass core 801. Accordingly, protection for the protrusion 810 can be provided by extending the first portion 831 further away from the edge of the package substrate 800. For example, a sidewall edge of the first portion 831 may be outside the footprint of the protrusion 810. Accordingly, when external objects approach the package substrate 800, they will contact the edge of the first portion 831 before contacting the protrusion 810 of the glass core 801. While no adhesive is shown in FIG. 8B, embodiments may include an adhesive between the stiffener 830 and the buildup layer 805.

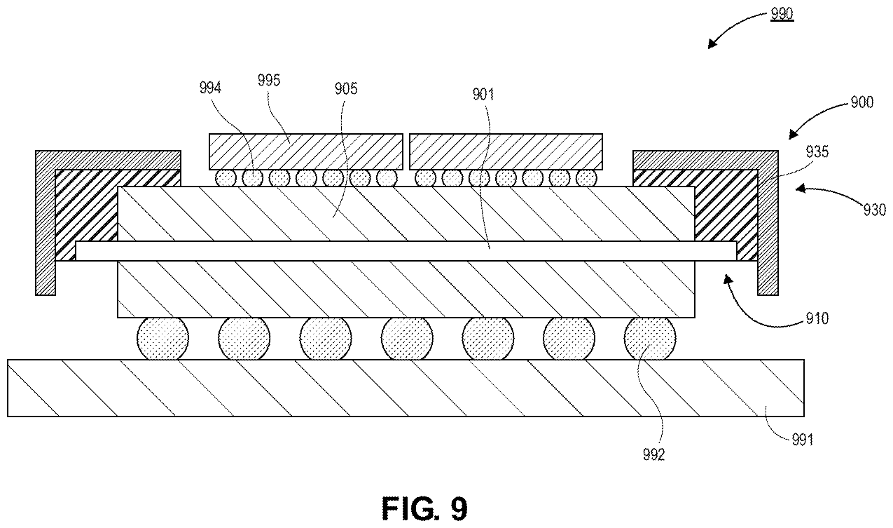

Referring now to FIG. 9, a cross-sectional illustration of an electronic system 990 is shown, in accordance with an embodiment. In an embodiment, the electronic system 990 may comprise a board 991, such as a printed circuit board (PCB). In an embodiment, the board 991 may be coupled to a package substrate 900 through interconnects 992. The interconnects 992 may be any suitable second level interconnect (SLI) architecture, such as solder balls, pins, or the like.

In an embodiment, the package substrate 900 may include a glass core 901 that is positioned between organic buildup layers 905. The glass core 901 may include protrusions 910 that extend out past the edge of the buildup layers 905. In order to provide mechanical protection for the protrusions 910, a stiffener 930 may be used. The stiffener 930 may include portions that wrap down along the sidewall of the package substrate 900 to cover at least the sidewall of the protrusions 910. An adhesive 935 may also fill gaps between the stiffener 930 and the package substrate 900 to provide additional mechanical support and protection. While a particular stiffener 930 architecture is shown in FIG. 9, it is to be appreciated that any stiffener architecture disclosed herein may be substituted into the electronic system 990 of FIG. 9.

In an embodiment, one or more dies 995 may be coupled to the package substrate 900 by interconnects 994. The interconnects 994 may be any suitable first level interconnect (FLI) architecture, such as solder, copper bumps, hybrid bonding interfaces, or the like. The dies 995 may be compute dies, such as a central processing unit (CPU), a graphics processing unit (GPU), an XPU, a communications die, or the like. Dies 995 may also include memory dies, or any other type of die suitable for use in an electronic system 990.

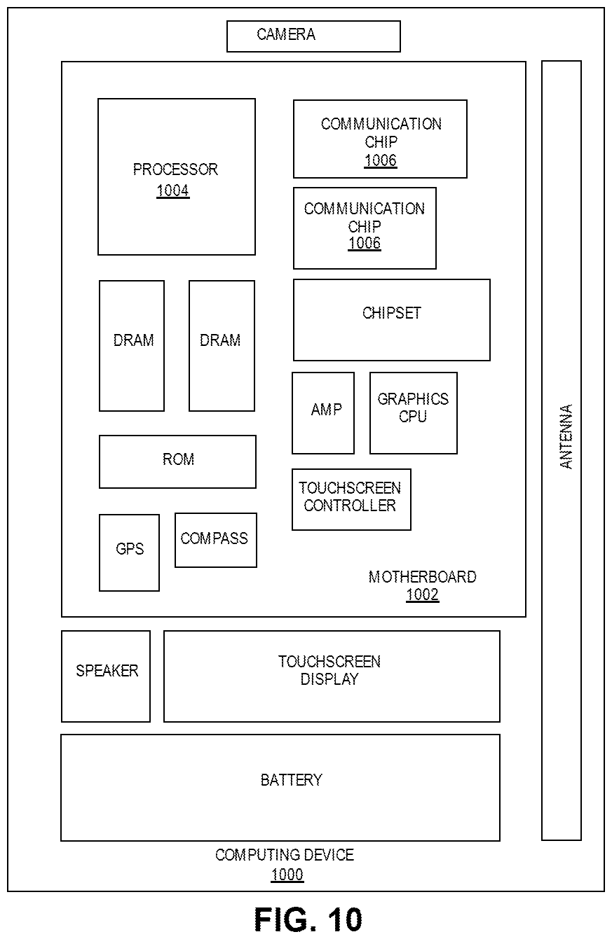

FIG. 10 illustrates a computing device 1000 in accordance with one implementation of the disclosure. The computing device 1000 houses a board 1002. The board 1002 may include a number of components, including but not limited to a processor 1004 and at least one communication chip 1006. The processor 1004 is physically and electrically coupled to the board 1002. In some implementations the at least one communication chip 1006 is also physically and electrically coupled to the board 1002. In further implementations, the communication chip 1006 is part of the processor 1004.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1006 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing device 1000 includes an integrated circuit die packaged within the processor 1004. In some implementations of the disclosure, the integrated circuit die of the processor may be part of an electronic package that includes a package substrate with a glass core that protrudes from an edge of the package substrate and a stiffener that covers the protrusion, in accordance with embodiments described herein. The term “processor” may refer to any device or portion of a device that processes electronic data from registers and/or memory to transform that electronic data into other electronic data that may be stored in registers and/or memory.

The communication chip 1006 also includes an integrated circuit die packaged within the communication chip 1006. In accordance with another implementation of the disclosure, the integrated circuit die of the communication chip may be part of an electronic package that includes a package substrate with a glass core that protrudes from an edge of the package substrate and a stiffener that covers the protrusion, in accordance with embodiments described herein.

In an embodiment, the computing device 1000 may be part of any apparatus. For example, the computing device may be part of a personal computer, a server, a mobile device, a tablet, an automobile, or the like. That is, the computing device 1000 is not limited to being used for any particular type of system, and the computing device 1000 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate, comprising: a first layer with a first width, wherein the first layer is a glass layer; a second layer under the first layer, wherein the second layer has a second width that is smaller than the first width; and a third layer over the first layer, wherein the third layer has a third width that is smaller than the first width; and a metallic structure with a first portion and a second portion, wherein the first portion is over a top surface of the substrate and the second portion extends away from the first portion and covers at least a sidewall of the first layer.

Example 2: the apparatus of Example 1, further comprising: an adhesive between the metallic structure and the substrate.

Example 3: the apparatus of Example 1 or Example 2, wherein the metallic structure is a stiffener.

Example 4: the apparatus of Examples 1-3, wherein a first end of the first layer and a second end of the first layer extend past sidewalls of the second layer and the third layer.

Example 5: the apparatus of Examples 1-4, wherein the first portion of the metallic structure is a ring around an outer edge of the top surface of the substrate.

Example 6: the apparatus of Examples 1-5, wherein a fold is provided between the second portion and the first portion.

Example 7: the apparatus of Examples 1-6, wherein the second portion covers an entire sidewall of the substrate, and wherein the metallic structure further comprises: a third portion, wherein the third portion extends laterally away from the second portion and is positioned under the substrate.

Example 8: the apparatus of Example 7, wherein the second portion is curved.

Example 9: the apparatus of Examples 1-8, wherein the second layer and the third layer both comprise organic buildup layers and a solder resist layer.

Example 10: the apparatus of Examples 1-9, wherein the first layer has a thickness between 100 μm and 1,000 μm.

Example 11: an apparatus, comprising: a first layer, wherein the first layer comprises a solid glass rectangular prism; a second layer under the first layer; a third layer over the first layer, wherein an end of the first layer extends past an end of the second layer and past an end of the third layer; and a stiffener with a first portion under the second layer and a second portion over the third layer, wherein an end of the stiffener is substantially coplanar with the end of the first layer.

Example 12: the apparatus of Example 11, further comprising: an adhesive between the first portion of the stiffener and the second portion of the stiffener, wherein the adhesive directly contacts the first layer.

Example 13: the apparatus of Example 11 or Example 12, wherein the adhesive is electrically conductive.

Example 14: the apparatus of Examples 11-13, wherein the stiffener extends over surfaces of the second layer and the third layer.

Example 15: the apparatus of Examples 11-14, wherein the first portion of the stiffener has a first width and the second portion of the stiffener has a second width that is substantially equal to the first width.

Example 16: the apparatus of Examples 11-15, wherein the second layer and the third layer both comprise organic buildup layers and a solder resist layer.

Example 17: the apparatus of Examples 11-16, wherein the first layer has a thickness between 100 μm and 1,000 μm.

Example 18: an apparatus, comprising: a board; a package substrate coupled to the board, wherein the package substrate comprises a glass core; a stiffener on the package substrate, wherein the stiffener includes vertical portions that cover sidewalls of at least the glass core; and a die coupled to the package substrate, wherein the stiffener surrounds an outer perimeter of the die.

Example 19: the apparatus of Example 18, wherein the stiffener wraps completely around a sidewall of the package substrate and covers at least a portion of a bottom of the package substrate.

Example 20: the apparatus of Example 18 or Example 19, wherein the apparatus is part of a personal computer, a server, a mobile device, a tablet, or an automobile.

What is claimed is:

1. An apparatus, comprising:
a substrate, comprising:
a first layer with a first width, wherein the first layer is a glass layer;
a second layer under the first layer, wherein the second layer has a second width that is smaller than the first width; and
a third layer over the first layer, wherein the third layer has a third width that is smaller than the first width; and
a metallic structure with a first portion and a second portion, wherein the first portion is over a top surface of the substrate and the second portion extends away from the first portion and covers at least a sidewall of the first layer.

2. The apparatus of claim 1, further comprising:
an adhesive between the metallic structure and the substrate.

3. The apparatus of claim 1, wherein the metallic structure is a stiffener.

4. The apparatus of claim 1, wherein a first end of the first layer and a second end of the first layer extend past sidewalls of the second layer and the third layer.

5. The apparatus of claim 1, wherein the first portion of the metallic structure is a ring around an outer edge of the top surface of the substrate.

6. The apparatus of claim 1, wherein a fold is provided between the second portion and the first portion.

7. The apparatus of claim 1, wherein the second portion covers an entire sidewall of the substrate, and wherein the metallic structure further comprises:
a third portion, wherein the third portion extends laterally away from the second portion and is positioned under the substrate.

8. The apparatus of claim 7, wherein the second portion is curved.

9. The apparatus of claim 1, wherein the second layer and the third layer both comprise organic buildup layers and a solder resist layer.

10. The apparatus of claim 1, wherein the first layer has a thickness between 100 μm and 1,000 μm.

11. An apparatus, comprising:
a first layer, wherein the first layer comprises a solid glass rectangular prism;
a second layer under the first layer;
a third layer over the first layer, wherein an end of the first layer extends past an end of the second layer and past an end of the third layer; and
a stiffener with a first portion under the second layer and a second portion over the third layer, wherein an end of the stiffener is substantially coplanar with the end of the first layer.

12. The apparatus of claim 11, further comprising:
an adhesive between the first portion of the stiffener and the second portion of the stiffener, wherein the adhesive directly contacts the first layer.

13. The apparatus of claim 12, wherein the adhesive is electrically conductive.

14. The apparatus of claim 11, wherein the stiffener extends over surfaces of the second layer and the third layer.

15. The apparatus of claim 11, wherein the first portion of the stiffener has a first width and the second portion of the stiffener has a second width that is substantially equal to the first width.

16. The apparatus of claim 11, wherein the second layer and the third layer both comprise organic buildup layers and a solder resist layer.

17. The apparatus of claim 11, wherein the first layer has a thickness between 100 μm and 1,000 μm.

18. An apparatus, comprising:
a board;
a package substrate coupled to the board, wherein the package substrate comprises a glass core;
a stiffener on the package substrate, wherein the stiffener includes vertical portions that cover sidewalls of at least the glass core; and
a die coupled to the package substrate, wherein the stiffener surrounds an outer perimeter of the die.

19. The apparatus of claim 18, wherein the stiffener wraps completely around a sidewall of the package substrate and covers at least a portion of a bottom of the package substrate.

20. The apparatus of claim 18, wherein the apparatus is part of a personal computer, a server, a mobile device, a tablet, or an automobile.
